(19) United States
(12) Patent Application Publication
(10) Pub. No.: US 2016/0072034 A1
(43) Pub. Date: Mar. 10, 2016

(54) METALS-SEMICONDUCTOR NANOWIRE COMPOSITES

(71) Applicant: THE REGENTS OF THE UNIVERSITY OF CALIFORNIA, Oakland, CA (US)

(72) Inventor: Nobuhiko KOBAYASHI, Sunnyvale, CA (US)

(21) Appl. No.: 14/783,820

(22) PCT Filed: May 15, 2014
(86) PCT No.: PCT/US14/38237

§ 371 Date: Oct. 9, 2015

Related U.S. Application Data
(60) Provisional application No. 61/825,978, filed on May 21, 2013.

(51) Int. Cl. H01L 35/26; H01L 35/34; H01L 35/32

(52) U.S. Cl. CPC H01L 35/26; H01L 35/32; H01L 35/34

(57) ABSTRACT

When fabricating thermoelectric devices using bulk semiconductor materials and single crystal substrates, the performance of the thermoelectric device can be limited by the interdependence between electrical conductivity, Seebeck coefficient, and thermal conductivity in the bulk semiconductor material. Additionally, the properties of bulk semiconductor materials can lead to expensive, bulky, and complex power generation systems. Thermoelectric devices can be fabricated using a metals-semiconductor composite and epitaxial nanowire percolation network architecture. Low cost, mechanically flexible, highly scalable, and high performance thermoelectric devices can be achieved due to the flexibility with the host semiconductor material, nanoparticle material, diameter and length of the nanowires, density and size of the embedded nanoparticles, angle of intersection of the nanowires, and choice of epitaxial growth conditions and fabrication processes in the metals-semiconductor composite and epitaxial nanowire percolation network architecture.

### FIELD OF THE DISCLOSURE

The present disclosure relates to a solid-state thermoelectric device. Particularly, but not exclusively, the present disclosure relates to a solid-state thermoelectric device comprising a network of randomly-oriented intersecting nanowires epitaxially grown with metallic nanoparticles embedded in a host semiconductor material.

### BACKGROUND OF THE DISCLOSURE

Thermoelectric power systems can be used for conversion of waste heat to electrical energy. The power systems can comprise a solid-state thermoelectric device fabricated using bulk semiconductor materials and single crystal semiconductor substrates. By utilizing a network of randomly-oriented, intersecting nanowires epitaxially grown with metallic nanoparticles embedded in a host semiconductor material, the performance limitations, high cost, mechanical inflexibility, and poor scalability of thermoelectric devices fabricated using bulk semiconductor materials can be alleviated.

### SUMMARY OF THE DISCLOSURE

This relates to thermoelectric devices and power systems for conversion of waste heat energy to electrical energy. Examples of this disclosure can be used to achieve low cost, mechanically flexible, and highly scalable thermoelectric devices with high energy conversion efficiency. The exemplary teachings of the disclosure can describe thermoelectric devices grown and fabricated using an architecture called the MSC-ENPN architecture.

The MSC-ENPN architecture can couple two material platforms: metals-semiconductor composite (MSC) and epitaxial nanowire percolation network (ENPN), taking advantage of the benefits of both MSC and ENPN to achieve high performance thermoelectric devices. The MSC-ENPN architecture can include a plurality of nanowires made of a metals-semiconductor composite with embedded metallic nanoparticles connected at fused nodes to form a three-dimensional network on a metal foil template.

### BRIEF DESCRIPTION OF THE DRAWINGS

FIG. 1 illustrates an exemplary thermoelectric power generator in which examples of this disclosure may be practiced.

FIG. 2 illustrates an exemplary solid-state thermoelectric device fabricated from bulk semiconductor material.

FIG. 3 illustrates a plot of the density of states as a function of energy for one-dimensional and three-dimensional materials.

FIG. 4a illustrates exemplary vertically-aligned nanowires grown on a substrate.

FIG. 4b illustrates exemplary nanowire film grown on a substrate.

FIG. 4c illustrates exemplary randomly-oriented intersecting nanowires grown on a substrate.

FIG. 5 illustrates a plot of Thermoelectric Figure of Merit for one-dimensional materials, Z(1D)Tₘ, compared to Thermoelectric Figure of Merit for three-dimensional materials, Z(3D)Tₘ, for four different packing densities.

FIG. 6a illustrates an exemplary pair of intersecting nanowires whose intersection at fused nodes can be formed during epitaxial growth.

FIG. 6b illustrates an exemplary pair of nanowires that touch and form a soft connection.

FIG. 7 illustrates an exemplary ENPN thermoelectric device.

FIG. 8 illustrates an exemplary MSC nanowire.

FIG. 9 illustrates an exemplary ENPN with nanowire growth formed with local atomic ordering regions.

FIG. 10 illustrates an exemplary MSC-ENPN thermoelectric device.

### DETAILED DESCRIPTION

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

This relates to thermoelectric power generators utilizing a metals-semiconductor composite epitaxial nanowire percolation network (MSC-ENPN) architecture. The MSC-ENPN architecture can be used to achieve low cost, high performance, and mechanically flexible thermoelectric devices for conversion of waste heat energy into electricity for applications such as the military, automotive industry, and industries invested in waste heat utilization systems. The performance, cost, and flexibility can be achieved through epitaxial coupling of nanometer-scale metals-semiconductor composite nanowires with efficient conversion of waste heat to electrical energy. The MSC-ENPN architecture couples two material platforms: metals-semiconductor composite (MSC) and epitaxial nanowire percolation network (ENPN), taking advantage of the benefits of both MSC and ENPN to achieve high performance thermoelectric devices. The MSC-ENPN architecture can include a plurality of nanowires made of a metals-semiconductor composite epitaxially connected to form a three-dimensional network where electrical current travels efficiently and heat transport can be minimized. The high electrical conductivity and low thermal conductivity achieved with MSC-ENPN can lead to high performance thermoelectric devices and thermoelectric power systems.

One type of thermoelectric device that can be used is a solid-state thermoelectric device fabricated using single-crystal semiconductor substrates and single-crystal bulk semiconductor materials. Single-crystal semiconductor substrates, such as high quality silicon, can be used. Single-crystal bulk semiconductor materials can include Group IV (e.g. silicon and germanium), Group III-V (e.g. InP and InSb), and Group V-VI (e.g. bismuth antimony telluride) materials. One issue can be the cost of bulk semiconductor thermoelectric devices, making them cost prohibitive for many applications. The single-crystal semiconductor substrates and bulk semiconductor materials can be very expensive in relation to the amount of electrical energy that the solid-state bulk semiconductor thermoelectric devices are capable of generating. Bulk semiconductor thermoelectric devices can also be limited by the feasibility and additional costs associated with large-scale fabrication, required by some applications such automobiles, electrical power generation plants, geothermal power generation plants, solar thermal power generation plants, and metal refineries. An additional issue can be that a mechanically flexible thermoelectric device that can easily conform to routinely heat-providing complex structures, needed for applications using components that have non-flat three-dimensional shapes including exhaust pipes and engine blocks in automobiles and industrial plants, can be difficult to achieve with thermoelectric devices fabricated from bulk semiconductor materials. A solution to the high cost, low efficiency, and mechanical inflexibility can be the MSC-ENPN architecture.

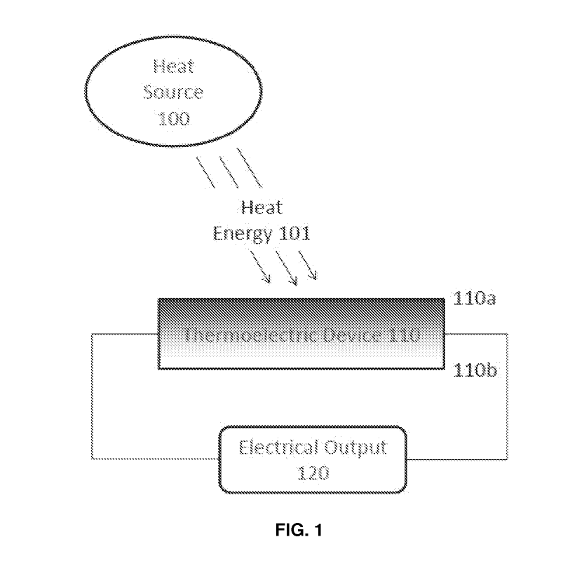

FIG. 1 illustrates an exemplary thermoelectric power generator system in which some of the examples of this disclosure may be practiced. Thermoelectric device 110 can absorb waste heat energy 101 from a heat source 100, such as the sun. One side 110a of thermoelectric device 110 can be at an elevated temperature due to the absorbed heat, while the other side 110b of the thermoelectric device 110 can be at a lower temperature. The temperature difference between sides 110a and 110b across the thermoelectric device 110 can generate a current. The current generated can then be extracted from the thermoelectric device to be used as electrical output 120.

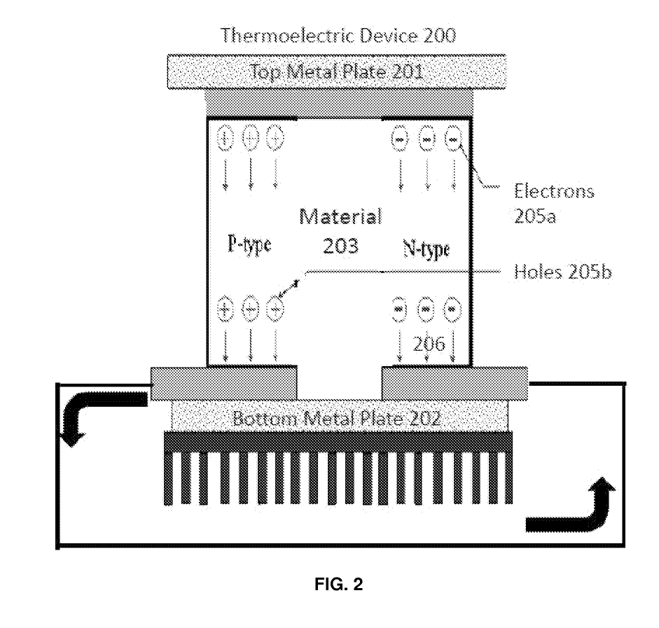

FIG. 2 shows an exemplary thermoelectric device 200. Thermoelectric device 200 can include a pair of substantially parallel plates with a material coupled between the plates. The pair of substantially parallel plates can include a top metal plate 201 and bottom metal plate 202 with material 203 coupled between the metal plates through which electrical charge and thermal energy conduct. The metal plates 201 and 202 can be maintained at different temperatures, causing a temperature gradient. For example, top metal plate 201 can become a heat source or maintained at an elevated temperature and bottom metal plate 202 can be maintained at a cooler or lower temperature. The temperature gradient can cause electrons 205a, if material 203 is an n-type semiconductor material (or holes 205b, if material 203 is a p-type semiconductor material), to migrate in a direction from the metal plate that can be at an elevated temperature, such as the top metal plate 201, to the metal plate that can be at a lower temperature, such as the bottom metal plate 202. This migration, shown by arrow 206, can be also referred to as diffusion. The diffusion can produce an open circuit voltage when the device is not connected to an external circuit. Consequently, the diffusion of electrons (or holes) can generate an electric field in a direction almost perpendicular to the metal plates. The magnitude of the electric field can depend on the distance between the metal plates 201 and 202, and the distance can depend on the thickness of the semiconductor material 203. The electric field can cause the electrons (or holes) to migrate in a direction that opposes the diffusion. This opposing migration can be referred to as drift. Thus, the electric field can cause a drift of electrons (or holes). This drift of electrons (or holes) can limit any short circuit current that can be generated by the diffusion when the device is shorted through an external circuit.

One way to characterize the performance of the semiconductor material 203 in thermoelectric device 200 can be with the Thermoelectric Figure of Merit ZT. Mathematically, the Thermoelectric Figure of Merit is defined as ZT=Tσα²/κ, where T is the temperature, σ is the electrical conductivity, α is the Seebeck coefficient, and κ is the thermal conductivity. The Seebeck coefficient is a measure of the thermoelectric power or the magnitude of an induced thermoelectric voltage of a material in response to a temperature gradient across the material. For maximum conversion of heat to electrical power, a high electrical conductivity, high Seebeck coefficient, and low thermal conductivity can be desired.

Higher values of ZT can lead to higher efficiency and larger amounts of electrical power generated from the absorbed thermal energy. A high performance thermoelectric device can be achieved through maximization of ZT. Maximization of ZT can be achieved by engineering all three intrinsic material properties: electrical conductivity, Seebeck coefficient, and thermal conductivity. By choosing a material with high electrical conductivity, high Seebeck coefficient, and low thermal conductivity, the electrical current can be maximized while preventing thermal shortage that could destroy the temperature gradient. However, the electrical conductivity, Seebeck coefficient, and thermal conductivity in a bulk semiconductor material may not be independent. For example, electrical conductivity and Seebeck coefficient can be inversely related, limiting the maximum Thermoelectric Figure of Merit ZT that can be achieved in a bulk semiconductor material. As a result, fabricating the thermoelectric devices using bulk semiconductor material can lead to low performance devices with poor efficiency from the constrained properties of the materials.

Reducing thermal conductivity in bulk semiconductor thermoelectric devices can also be challenging because the materials used to provide high electrical conductivity also tend to have high thermal conductivity. For thermal conductivity, both phonons and electrons can contribute, so minimizing both the mobility of phonons and the mobility of electrons can be beneficial in achieving lower thermal conductivity. However, minimizing the mobility of electrons can then lead to a lower electrical conductivity. Conversely, increasing the electrical conductivity can lead to higher thermal conductivity. This compromise between thermal conductivity and electrical conductivity can become an additional limitation to ZT values achieved with bulk semiconductor materials.

To increase the electrical conductivity in bulk semiconductor devices, one way could be to increase the volume of the bulk semiconductor material 203. A large volume may lead to a higher electrical energy output, but the epitaxial growth and fabrication of a large volume of the bulk semiconductor material can be difficult and costly. If the epitaxial growth and fabrication of a large volume of a given bulk semiconductor material can be achieved, the larger volume can lead to higher electrical energy output, but maximum ZT values from the bulk semiconductor material can still be insufficient for certain applications that require large amounts of electrical energy or open circuit voltage. A large open circuit voltage can be obtained by connecting a large number of thermoelectric devices in series, but connecting several thermoelectric devices in series can lead to bulky and complex systems. Additionally, large volume bulk semiconductor material can result in thermoelectric devices that are mechanically inflexible due to not only the large volume of the material, but also due to the possible need for thick and rigid substrates to support the volume. One further issue with increasing the volume of the semiconductor material can be the insufficient availability of a large amount of semiconductors in bulk form, limiting the scalability of the bulk semiconductor thermoelectric devices. Due to the challenges and the compromises of large volume bulk material, the high expense of the substrates and the limited availability of both semiconductor bulk material and the single-crystal semiconductor substrates, fabricating thermoelectric devices using a large volume of bulk semiconductor material may not be feasible.

ZT values for bulk semiconductor materials can be small and can limit the performance of the thermoelectric device, so one alternative can be to use semiconductor nanowires instead of bulk semiconductor material. The ability to achieve higher ZT values with semiconductor nanowires can be attributed to quantum confinement and their one-dimensional properties. One-dimensional semiconductors can give the ability to increase electrical conductivity and Seebeck coefficient, while simultaneously reducing the thermal conductivity. The quantum confinement can result in increased electron mobility, and therefore higher σ values or electrical conductivity in semiconductor nanowires compared to bulk semiconductor materials.

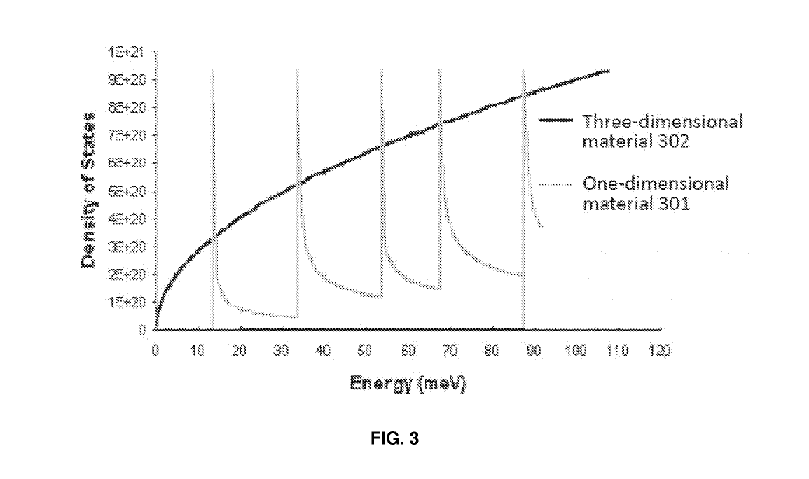

Increased Seebeck coefficient can be achieved due to the electronic density of states. The electronic density of states in a given semiconductor material is the number of states available at each energy level that can be occupied by electrons. A semiconductor material can have a value called the Fermi energy level. The Fermi energy level is a property that represents the highest energy occupied for an electron at a temperature of 0K for a given material. For bulk semiconductor materials, which are three-dimensional, the density of states can be continuous as a function of energy. On the other hand, electrons in one-dimensional materials, such as nanowires, are confined laterally and can thus occupy energy levels that are different from the continuous energy bands in bulk semiconductors. FIG. 3 shows a plot of the density of states for a one-dimensional material 301, such as a nanowire, and a three-dimensional material 302, such as bulk semiconductor. The density of states for a one-dimensional material can descend gradually with energy and then increase with a sharp peak or spike. Modification of the location of the sharp peaks, in the one-dimensional material, to be closer to the Fermi energy level can lead to an enhancement of the Seebeck coefficient, further resulting in an enhancement of the thermoelectric power factor, σS². One method to modifying location of the sharp peaks in the density of states for semiconductor nanowires can be through the size of the nanowires. These sharp peaks are absent in bulk semiconductors. For three-dimensional materials, aligning the density of states to the Fermi level may not be possible and thus Seebeck coefficient values can become limited by properties of the material.

Thermal conductivity in bulk semiconductor material can be limited to the properties of the materials. On the other hand, for nanowires, reduced thermal conductivity can be achieved by altering the size of the nanowires. The size of the nanowires can be optimized to approach the phonon mean free path length. The mean free path length of a phonon is the distance the phonon travels before undergoing a collision. By making the size of the nanowires close to the phonon mean free path length, the scattering of the phonons and the phonon density of states can be tuned to cause a decrease in the thermal conductance. Additionally, phonon transport can be suppressed in one-dimensional semiconductors, resulting in smaller lattice thermal conductivity.

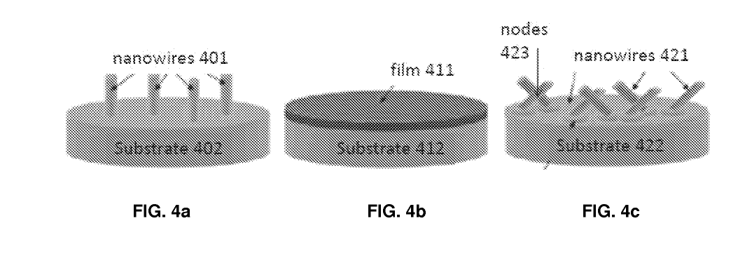

A thermoelectric device can use a plurality of single-crystal semiconductor nanowires on a substrate. One way to epitaxially grow the nanowires is shown in FIG. 4a. Vertically aligned nanowires 401 can be formed on a single-crystal substrate 402. One problem with vertically aligned nanowires can be the ability to maintain the one-dimensional characteristics while simultaneously having a high packing density. The packing density is the ratio of the total volume occupied by all the nanowires in a device to the total device volume. The packing density can be important because the packing density can determine the total energy that can be produced for conversion. Without a high packing density, attaining a higher ZT may not offer a higher total output power. To generate a given output power, ZT may have to be increased by a factor inverse of the packing density of the nanowires.

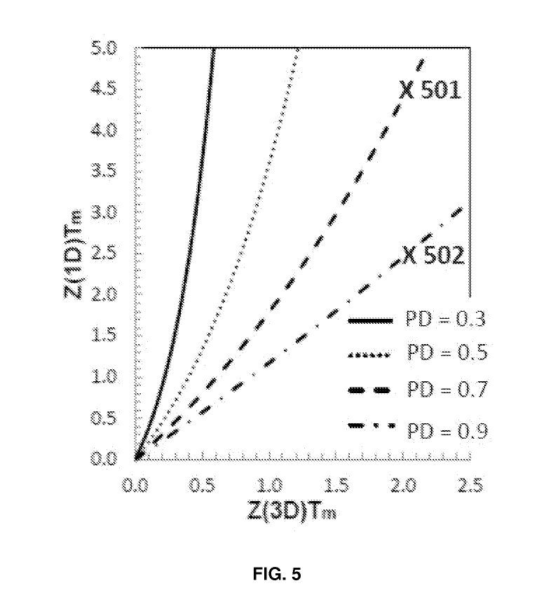

The effect of packing density for a given ZT value can be shown by the plot given in FIG. 5. Thermoelectric Figure of Merit for one-dimensional materials, Z(1D)Tₘ, can be compared to the Thermoelectric Figure of Merit for three-dimensional materials, Z(3D)Tₘ, for the same output power. Tₘ=(T_{H}+T_{L})/2 where T_{H} and T_{L} represent high and lower temperatures that create a temperature difference and four different packing densities, P_{D}, are plotted. The plot shows that for nanowires, a packing density higher than 70% can achieve output power greater than or equal to that of bulk semiconductor material. For example, data point 501 shows that nanowires with Z(1D)Tₘ=4.5 and packing density of PD=70% can achieve a comparable match to a bulk semiconductor material with Z(3D)Tₘ=2.0. However, if the packing density is less than 70%, a higher Z(1D)Tₘ value, greater than 4.5, may be needed for the nanowires in order to have a comparable match to the output power of bulk semiconductor material with Z(3D)Tₘ=2.0. On the other hand, if the packing density of the nanowires is 90%, a lower Z(1D)Tₘ value of about 2.5, shown by data point 502, for the nanowires can achieve a comparable match to the output power of bulk semiconductor material with Z(3D)Tₘ=2.0. These examples can be used to show that attaining a ZT value higher than that of bulk by implementing nanowires does not necessarily offer higher total output power without considering packing density.

An alternative to vertically aligned nanowires that may not have a packing density issue can be a nanowire thin film shown in FIG. 4b. Nanowire thin film 411 can be formed on top of a single-crystal substrate 412. Nanowire thin film 411 can comprise a bundle of nanowires lying on top of the substrate. The bundle of nanowires may not necessarily be well connected with each other because the nanowires can be mechanically manufactured and then synthesized separately. As a result, using nanowire thin film 411 may lead to lower electrical conductivity due to the poorly connected nanowires that merely touch to form soft connections.

One solution to overcome the packing density issue encountered with vertically aligned nanowires and the connection issue encountered with nanowire thin films can be with a nanowire composite, shown in FIG. 4c. Nanowire composite can comprise of a plurality of randomly-oriented intersecting nanowires 421 disposed on a non-single crystal substrate 422. A large number of intersecting nanowires 421 can form a three-dimensional epitaxial nanowire percolation network (ENPN) through which electrical carriers and heat travel. The nanowires in the ENPN can have nodes 423 where two or more nanowires 421 intersect. The nanowires 421 in the ENPN can be structurally fused together at the nodes 423 where the intersections can be formed during epitaxial growth.

The ENPN architecture can have increased packing density through optimization of the diameter of the nanowires. The packing density can be increased because an increased nanowire diameter can decrease the amount of physical separation between the nanowires. By increasing the nanowire diameter, packing densities in the ENPN greater than 70% can be achieved and high ZT values can lead to high output power. The ENPN architecture can achieve high packing densities while retaining the one-dimensional characteristics, a problem that may arise with vertically-aligned nanowires.

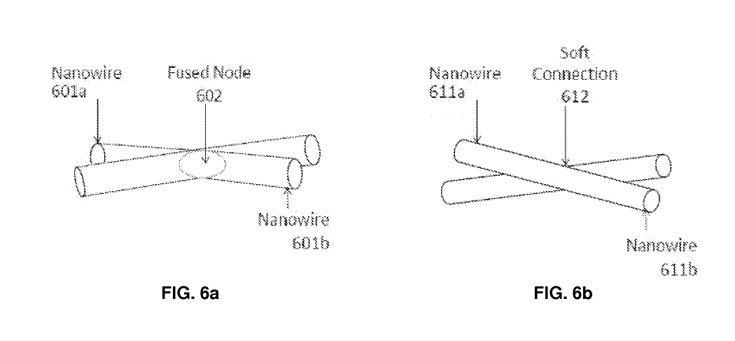

The connectivity issue with the nanowire thin film can be overcome with the nodes in the ENPN. The nodes can play a substantial role in affecting the electrical conductivity because the carriers in the nanowires can move freely and may not be interrupted by any physical interfaces, which can exist in non-epitaxial nanowire networks or in the nanowire thin film where the nanowires merely touch to form soft connections. FIG. 6a shows a structurally fused node from the ENPN architecture. Nanowires 601a and 601b intersect at fused node 602, whose intersection can be formed during epitaxial growth. FIG. 6b shows nanowires 611a and 611b that merely touch and have a soft connection 612. Intersecting the nanowires through the fused nodes prevents any limitations on electrical and thermal conductivity due to poor connectivity of the nanowires.

In some examples, the ENPN can be grown with conditions that take into account the local connectivity of the nanowires. The local connectivity of the nanowires at the nodes may depend on local geometrical factors, such as the angle at which the nanowires intersect and the directions along which intersections are oriented. In some examples, the nanowire length or the diameter of the nanowires can be altered to reduce the thermal conductivity.

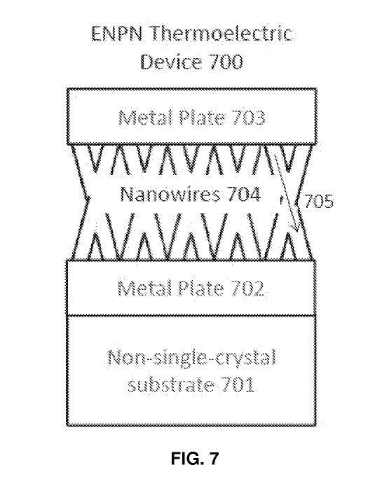

An exemplary ENPN thermoelectric device is shown in FIG. 7. ENPN thermoelectric device 700 can comprise a bottom metal plate 702 formed on a non-single-crystal substrate 701, a plurality of semiconductor nanowires 704 formed on the bottom metal plate 702, and a top metal plate 703 formed on the plurality of semiconductor nanowires 704. The bottom and top metal plates 702 and 703 can act as electrodes. One electrode, such as the top metal plate 703, can be maintained at an elevated temperature above the other electrode, such as the bottom metal plate 702, to create a temperature gradient. Electrical charge can flow and heat can travel through the plurality of nanowires 704. In n-type nanowires, the electrons (or holes in p-type nanowires) can diffuse to the cold side, shown by arrow 705 traveling from the top metal plate 703 to bottom metal plate 702, resulting in an electrical open circuit voltage appearing on any external circuit connected between the two metal plates.

The intersecting nanowires in the nanowire composite can also lead to higher performance thermoelectric devices because of the reduced drift that opposes the desired diffusion of electrons to the cold metal plate. The reduced drift can result from the long-axis of the nanowires not being perpendicular to the two metal plates, which means that the electric field generated by the diffusing electrons (or holes) may not be necessarily perpendicular to the metal plates. The fused nodes at intersections can provide multiple paths for electrons (or holes) to travel in different directions. The changing directions of diffusing electrons (or holes) can create many electric field vectors that cancel out to reduce the drift. Thus, a smaller total drift can be attained that opposes diffusion to increase the open circuit voltage.

The intersecting nanowires can also provide reduced thermal conductivity because of the fused nodes created by the intersecting nanowires. The nodes can disrupt heat conductance when the phonon mean free path length is larger than the mean distance between two nodes. This however may not necessarily disrupt electron transport because the electron mean free path can be much shorter than the mean distance between the two nodes. From a quantum mechanical point of view, heat and electrons have specific wavelengths, and the wavelength associated with heat conduction can be much longer than that associated with electrons. Thus, a plurality of intersecting nanowires may disrupt the heat flow but does not necessarily reduce the diffusion of electrons (or holes). The ability to independently adjust the thermal and electrical conductivity of the nanowires in the ENPN can be used to generate a more efficient thermoelectric device.

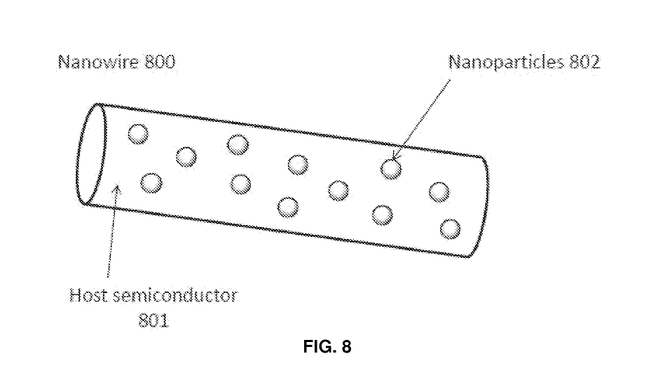

The MSC-ENPN architecture can utilize the one-dimensional characteristics achieved with randomly-oriented intersecting nanowires of the ENPN architecture. In addition to the improved performance that can be obtained with the ENPN, the MSC-ENPN architecture can obtain even further performance improvements by utilizing the MSC platform. The MSC platform comprises a semiconductor material with metallic nanoparticles embedded within. By embedding a plurality of metallic nanoparticles in a host semiconductor material, lower thermal conductivity and higher ZT values are possible. A nanowire that utilizes the MSC platform is shown in FIG. 8. Nanowire 800 comprises a host semiconductor 801 with embedded nanoparticles 802. There can be a large degree of freedom with MSC as the material properties can be controlled by tuning the volume density and size of the nanoparticles.

Embedding metallic nanoparticles in the semiconductor material can help achieve a high ZT value with lower thermal conductivity due to the metal-semiconductor interfaces created between the metallic nanoparticles and host semiconductor material. A large number of metal-semiconductor interfaces present in a MSC can suppress the transport of mid-long wavelength phonons to reduce their lattice contribution to the thermal conductivity of the material. Theoretically, a thermal conductivity lower than the alloy limit can be achieved with MSC.

Additionally, the metal-semiconductor interfaces can also lead to a Schottky barrier created between the metallic nanoparticles and host semiconductor material. The Schottky barrier is a potential barrier that can be formed and can be used to filter the electron energy distribution. Filtering the electron energy distribution can create a large difference between the average energy of the conduction electrons and the Fermi energy level, which in turn can lead to a high Seebeck coefficient, while filtering of the electron energy distribution can lead to a loss in electrical conductivity. The loss in electrical conductivity can be negligible and the high electron density in the metallic nanoparticles can compensate for this loss. Higher ZT values can be achieved by adjustment of the Schottky barrier height.

The MSC platform also allows for high ZT values by increasing the electrical conductivity while simultaneously decreasing the thermal conductivity. The electrical conductivity at a given doping concentration can be increased by having electrons associated with metallic nanoparticles, while the electronic contribution to thermal conductivity can be decreased by changing the electronic band structure of the host semiconductor.

To help overcome the limitations with performance and cost of thermoelectric devices fabricated from bulk semiconductor materials, the MSC-ENPN architecture can be used. The MSC-ENPN architecture is a material platform in which the MSC and ENPN platforms are coupled and the material can receive the performance enhancements from both MSC and ENPN platforms. The MSC-ENPN architecture can employ a plurality of randomly-oriented nanowires that form a three-dimensional network. The nanowires can be made of metallic nanoparticles embedded into a host semiconductor material. The nanowires can epitaxially intersect with each other at nodes, and can be grown directly on a template, such as a metal foil. Low cost can be achieved as the MSC-ENPN architecture does not require expensive single-crystal substrates and instead can be directly formed on a metal foil.

Maximization of ZT can be achieved by engineering all three intrinsic material properties: electrical conductivity, Seebeck coefficient, and thermal conductivity. The quantum confinement of the electrons and phonons in the one-dimensional nanowires of the MSC-ENPN can lead to higher attainable ZT values. A higher output power can be achieved by adjusting the separation between the nanowires leading to higher packing density values. Higher electrical conductivity in the MSC-ENPN can be achieved from the epitaxially fused nodes that create connections for electrical carriers and heat to efficiently travel through. The Seebeck coefficient at a given doping concentration can be increased by using electron filtering associated with the Schottky barriers created between the metallic nanoparticles and the host semiconductor material. The nanowire size can be optimized to tailor the density of states to align with the Fermi level of the MSC material to achieve even higher Seebeck coefficient values. The nanowire size can also be changed to affect the scattering of phonons, the phonons density of states, and the phonon transport, potentially resulting in lower thermal conductivity. Lattice contribution to thermal conductivity can be decreased from the embedded metallic nanoparticles that introduce negligible degradation in crystallinity of the host semiconductor material. Furthermore, a large number of nodes, where multiple nanowires can intersect, can reduce the overall thermal conductivity. Additionally, the electronic contribution to thermal conductivity can be decreased by changing the electronic band structure of the host semiconductor material.

In addition to the MSC-ENPN architecture being capable of increased energy conversion efficiency, the MSC-ENPN can have reduced costs compared to thermoelectric devices fabricated from bulk semiconductor material due to the ability to use non-single-crystal substrates. The surface of non-single-crystal substrates can provide long-range atomic ordering to “seeds” of nanowires. An individual nanowire can “locally” see atomic ordering within an area on the scale that is comparable to the size of a nanowire seed. The individual nanowire may not be able to distinguish between two cases: disposed on a single-crystal substrate or disposed on a small crystallite on a non-single-crystal plate. The major difference between the two cases can be the two locations on the surface of a single-crystal substrate correlated with its specific crystallographic translational vectors, whereas two small crystallites that can exit on a non-single crystal metal plate layer may not be geometrically correlated. As long as the geometrical organization among a group of nanowires is not required, a non-single-crystal substrate can be used.

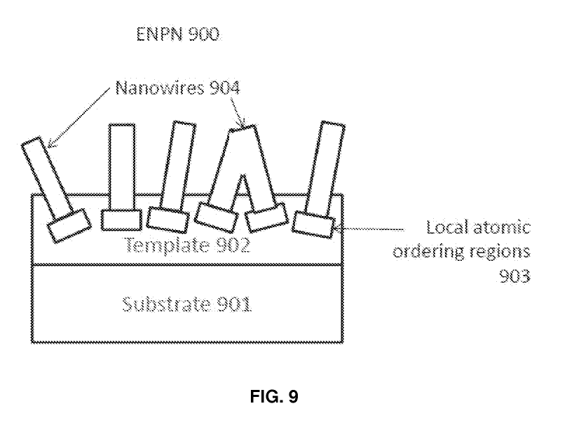

FIG. 9 shows an exemplary ENPN grown on a substrate utilizing a local regular atomic arrangement for the growth of the nanowires. ENPN 900 comprises of a template 902 that can be formed on top of substrate 901. Template 902 can have local atomic ordering regions 903 allowing for the randomly-oriented nanowires 904 to grow. The template 902 can work as both an epitaxial template and an electrode. In some examples, template 902 can be a metal silicide formed by having hydrogenated silicon and a metal, such as copper, react. Substrate 901 can be a non-single-crystal substrate or a single-crystal substrate.

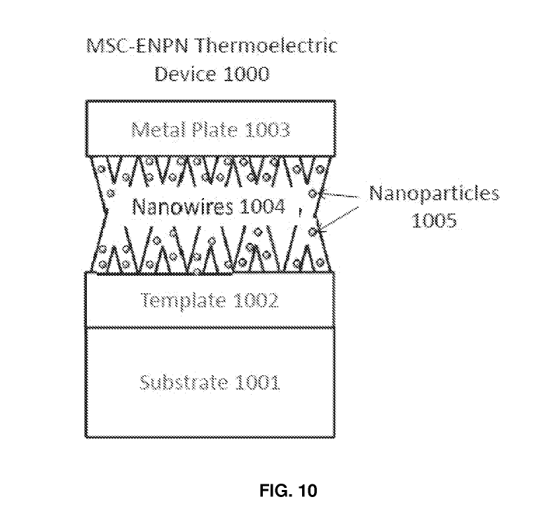

An exemplary MSC-ENPN thermoelectric device is shown in FIG. 10. MSC-ENPN thermoelectric device 1000 can comprise if a substrate 1001. Template 1002 can be formed on top of substrate 1001 and can act as a metal plate or electrode. Randomly-oriented intersecting nanowires 1004 can then be grown on top of template 1002. Nanowires 1004 can utilize the MSC platform and comprise of a host semiconductor material with nanoparticles 1005 embedded within the host semiconductor material. Metal plate 1003 can be formed on top of nanowires 1004.

In addition to optimization of the material properties of the MSC-ENPN material coupled between the metal electrodes, the performance of the thermoelectric device can be improved through fabrication. In some examples, the thermal conductance can be reduced by optimizing the thermal impedance mismatch between the one-dimensional nanowires and the two-dimensional metallic template. A large thermal impedance mismatch between the one-dimensional nanowires and the template or metal electrode can result in further reduction in overall thermal conductivity, while electrical transport can remain essentially Ohmic.

In some examples, the top electrode can be fabricated onto a network of nanowires such that a reduced electrical series resistance can be achieved. Low contact resistance can reduce any parasitic electrical losses. In some examples, the network of nanowires can be epitaxially connected to the bottom electrode ensuring low electrical series resistance. In some examples, a low temperature bonding technique such as wafer bonding based on covalent chemical bonding between two similar or dissimilar materials can be used to form the top metal electrode to the ensemble of randomly-oriented nanowires.

In some examples, a medium or filler material can be used in between the top and bottom electrodes. The material chosen for the medium can have low thermal conductivity, low electrical conductivity, and can withstand high temperatures. Example material can be a conformal dielectric coating used to protect the sidewalls of the nanowires. Dielectric coating can be deposited using several different techniques such as atomic layer deposition. In some examples, spin-on-glass dielectric can be formed on the ENPN top surface. The spin-on-glass can be etched back to expose tips of the nanowires for the top electrode to be disposed on. In some examples, medium or filler material can be chosen such that its mechanical properties allow for improved robustness of the thermoelectric device. In some examples, an infiltration material can be applied between the electrodes. In some examples, a dielectric layer can be formed on top of the infiltration material.

In some examples, a two-step growth process can be used to grow the nanowires. With a two-step growth process, the ENPN can be grown under specific growth conditions to promote axial growth, growing in the direction of the long axis of the nanowires. The growth conditions can then be changed to promote lateral growth, such that the growth can now be in a direction perpendicular to the long axis of the nanowires. The lateral growth can form a continuous film that connects the tips of the nanowires and then top electrode can be disposed on top. In some examples, a metal barrier layer can be implemented as diffusion barriers for low electrical contact resistance at high temperatures.

In some examples, the intersecting nanowires can be grown on a non-single crystal substrate so that the semiconductor nanowires are not induced to grow in a highly-structured vertical arrangement. In some examples, the template may be made of any inexpensive metallic material such as copper foils, stainless steel foils, or alloys with silicide. In some examples, the nanowires can be formed on a hydrogenated-microcrystalline silicon (mc-Si:H) template. In some examples, the mc-Si:H template can be prepared on a non-single crystalline surface such as glass substrate. In some examples, the top and bottom electrode can comprise of the same material. In some examples, the top and bottom electrode can comprise of different materials. In some examples, the nanowires can be grown on a single-crystal substrate such as GaAs. In some examples, the host semiconductor material of the nanowires can be chosen based on material resistance and robustness at high temperatures. For example, host semiconductor material can be Silicon, a binary alloy, such as InP, InAs, and SiGe, or ternary alloys, such as InGaSb and InAsSb. In some examples, the nanoparticles can be made of ErAs or ErSb. In some examples, the nanoparticle material can be chosen to lattice match to the host semiconductor material.

In some examples, the nanoparticles and host semiconductor material can be grown using chemical vapor deposition (CVD) techniques or vapor phase epitaxy (VPE). The plurality of nanowires 404 may be grown using crystal mechanisms of one-dimensional semiconductors on non-single crystal surfaces, lowering the cost of the ENPN architecture. For example, SiGe nanowires and Group III-V semiconductor (e.g., InSb, InP) nanowires may be grown on a silicide surface. Silicides can be formed by, for example, solid phase reaction between a transition metal and silicon at high temperatures. In some examples, Group IV or Group V-VI materials can be used to form a plurality of nanowires.

In some examples, the nanoparticle growth conditions can be optimized. The growth of the nanoparticles can be performed using techniques such as pulsing the metals or functionally varying the metal precursor relative to the background concentration. The pulsing method can be done by turning off the matrix material flux and pulsing the nanoparticle precursors. Following this, the matrix material flux can be resumed. In some examples, the plasma can be pulsed to be species selective. In some examples, the material sources can be constantly run for stable output and switching can occur between run and vent lines.

Additionally, the thermoelectric power system and MSC-ENPN thermoelectric device can be mechanically flexible. In some examples, over-wrap p- and n-type thermoelectric devices can be connected in series. In some examples, the substrate can be a mechanically flexible metal foil substrate that can be fabricated to cover a large surface area with three-dimensional curvature. The MSC-ENPN architecture can offer significant flexibility in module design. In some examples, the nanowires can be displaced between the two electrodes and can be horizontally assembled. In some examples, the nanowire diameter can be optimized to account for the mechanical strength of the thermoelectric device.

In addition to optimizing the nanowire diameter to account for mechanical strength of the thermoelectric device. The nanowire diameter can be adjusted to tune the electrical and thermal properties of the MSC-ENPN. The resistance of the nanowire can be independent of the length of the nanowires. However, the diameter of the nanowire can impact the degree to which the properties associated with the surface morphology contribute to the physical properties. For example, surface states existing on nanowires can influence the electrical transport properties. Additionally, any structure inhomogeneity, such as ionized impurities, defects, and fluctuation in chemical composition, that exists in a nanowire can change the electrical transport properties. In some examples, the growth parameters can be adjusted to alter the nanowire morphology. Growth parameters can include substrate temperature, chamber pressure, and plasma activation.

The MSC-ENPN architecture can be useful for large-scale implementations for generating electricity for any mechanism that captures or generates heat, such as solar cells, automobiles, manufacturing, power generation, refineries, industrial power plants, and commercial buildings. MSC-ENPN can be effectively used in self-contained vehicles such as submarines, space crafts, or the like, because it does not require solar heat to generate electricity. In comparison to thermoelectric devices made of bulk semiconductor material, thermoelectric devices based on the MSC-ENPN architecture can be utilized to attain low cost, high performance devices that are mechanically flexible, scalable, and efficient.

In some examples, a thermoelectric device is disclosed. The thermoelectric device may comprise: a substrate; a plurality of electrodes, at least one electrode coupled to the substrate; and a plurality of nanowires disposed between the plurality of electrodes, wherein at least one of the plurality of nanowires includes embedded nanoparticles. Additionally or alternatively to one or more examples disclosed above, in other examples, the plurality of nanowires are randomly-oriented. Additionally or alternatively to one or more examples disclosed above, in other examples, at least two of the plurality of nanowires intersect. Additionally or alternatively to one or more examples disclosed above, in other examples, the at least two of the plurality of nanowires intersect at one or more nodes and at least one of a size of the plurality of nanowires and a mean distance between two of the one or more nodes approaches a phonon mean free path length. Additionally or alternatively to one or more examples disclosed above, in other examples, the plurality of nanowires forms a three-dimensional network. Additionally or alternatively to one or more examples disclosed above, in other examples, the plurality of nanowires are formed from at least one of Silicon, Indium Phosphide (InP), Indium Arsenide (InAs), Indium Gallium Antimonide (InGaSb), and Indium Arsenide Antimonide (InAsSb), and wherein the embedded nanoparticles are formed from at least one of Erbium Arsenide (ErAs) and Erbium Antimonide (ErSb). Additionally or alternatively to one or more examples disclosed above, in other examples, a thermal impedance of the plurality of nanowires is matched to a thermal impedance of the embedded nanoparticles. Additionally or alternatively to one or more examples disclosed above, in other examples, the embedded nanoparticles are made of a metallic material. Additionally or alternatively to one or more examples disclosed above, in other examples, the thermoelectric device further comprises: a template coupled to the plurality of nanowires. Additionally or alternatively to one or more examples disclosed above, in other examples, the template is at least one of a metal foil or a metal silicide. Additionally or alternatively to one or more examples disclosed above, in other examples, the template included in one of the plurality of electrodes. Additionally or alternatively to one or more examples disclosed above, in other examples, a thermal impedance of the template is matched to a thermal impedance of the plurality of nanowires. Additionally or alternatively to one or more examples disclosed above, in other examples, the substrate is a non-single crystal substrate. Additionally or alternatively to one or more examples disclosed above, in other examples, the substrate is a mechanically flexible substrate. Additionally or alternatively to one or more examples disclosed above, in other examples, a packing density of the plurality of nanowires is greater than 0.70 and a thermoelectric figure of merit is greater than 4.5.

In some examples, a method of forming a thermoelectric device is disclosed, the method may comprise: forming a plurality of nanowires disposed between a plurality of electrodes, wherein the plurality of nanowires includes embedded nanoparticles. Additionally or alternatively to one or more examples disclosed above, in other examples, forming the plurality of nanowires comprises a multi-step growth process. Additionally or alternatively to one or more examples disclosed above, in other examples, the multi-step growth process includes a first step configured for axial growth and a second step configured for lateral growth. Additionally or alternatively to one or more examples disclosed above, in other examples, forming the embedded nanoparticles includes at least one of pulsed growth and creating a difference between a metal precursor and a background concentration.

While various examples have been described above, it should be understood that they have been presented by way of example only, and not by way of limitation. Although examples have been fully described with reference to the accompanying drawings, the various diagrams can depict an example architecture or other configuration for this disclosure, which is done to aid in the understanding of the features and functionality that can be included in the disclosure. The disclosure is not restricted to the illustrated exemplary architectures or configurations, but can be implemented using a variety of alternative architectures and configurations. Additionally, although the disclosure is described above in terms of various examples and implementations, it should be understood that the various features and functionality described in one or more of the examples are not limited in their applicability to the particular example with which they are described. They instead can be applied alone or in some combination, to one or more of the other examples of the disclosure, whether or not such examples are described, whether or not such features are presented as being part of a described example. Thus, the breadth and scope of the present disclosure should not be limited by any of the above-described examples.

What is claimed:

1. A thermoelectric device comprising:
a substrate;
a plurality of electrodes, at least one electrode coupled to the substrate; and
a plurality of nanowires disposed between the plurality of electrodes, wherein at least one of the plurality of nanowires includes embedded nanoparticles.

2. The thermoelectric device of claim 1, wherein the plurality of nanowires are randomly-oriented.

3. The thermoelectric device of claim 1, wherein at least two of the plurality of nanowires intersect.

4. The thermoelectric device of claim 3, wherein the at least two of the plurality of nanowires intersect at one or more nodes and at least one of a size of the plurality of nanowires and a mean distance between two of the one or more nodes approaches a phonon mean free path length.

5. The thermoelectric device of claim 1, wherein the plurality of nanowires forms a three-dimensional network.

6. The thermoelectric device of claim 1, wherein the plurality of nanowires are formed from at least one of Silicon, Indium Phosphide (InP), Indium Arsenide (InAs), Indium Gallium Antimonide (InGaSb), and Indium Arsenide Antimonide (InAsSb), and wherein the embedded nanoparticles are formed from at least one of Erbium Arsenide (ErAs) and Erbium Antimonide (ErSb).

7. The thermoelectric device of claim 1, wherein a thermal impedance of the plurality of nanowires is matched to a thermal impedance of the embedded nanoparticles.

8. The thermoelectric device of claim 1, wherein the embedded nanoparticles are made of a metallic material.

9. The thermoelectric device of claim 1, further comprising:
a template coupled to the plurality of nanowires.

10. The thermoelectric device of claim 9, wherein the template is at least one of a metal foil or a metal silicide.

11. The thermoelectric device of claim 9, wherein the template is included in one of the plurality of electrodes.

12. The thermoelectric device of claim 9, wherein a thermal impedance of the template is matched to a thermal impedance of the plurality of nanowires.

13. The thermoelectric device of claim 1, wherein the substrate is a non-single crystal substrate.

14. The thermoelectric device of claim 1, wherein the substrate is a mechanically flexible substrate.

15. The thermoelectric device of claim 1, further comprising:
a continuous film disposed on the plurality of nanowires and configured to couple a first side of the plurality of nanowires.

16. The thermoelectric device of claim 1, wherein a packing density of the plurality of nanowires is greater than 0.70 and a thermoelectric figure of merit of the thermoelectric device is greater than 4.5.

17. A method of forming a thermoelectric device comprising:
forming a plurality of nanowires disposed between a plurality of electrodes, wherein the plurality of nanowires includes embedded nanoparticles.

18. The method of claim 17, wherein forming the plurality of nanowires comprises a multi-step growth process.

19. The method of claim 18, wherein the multi-step growth process includes a first step configured for axial growth and a second step configured for lateral growth.

20. The method of claim 17, wherein forming the embedded nanoparticles includes at least one of pulsed growth and creating a difference between a metal precursor and a background concentration.
